(19) United States
(12) Patent Application Publication
(10) Pub. No.: US 2011/0174365 A1
(43) Pub. Date: Jul. 21, 2011

(54) SYSTEM AND METHOD FOR FORMING ROOFING SOLAR PANELS

(76) Inventors: Kenneth C. Drake, Midway, UT (US); Donovan Drake, Acton, CA (US)

(21) Appl. No.: 13/008,652

(22) Filed: Jan. 18, 2011

Related U.S. Application Data
(60) Provisional application No. 61/295,842, filed on Jan. 18, 2010.

(51) Int. Cl. H01L 31/0264; H01L 31/02; H01L 31/04; H01L 31/0376; H01L 31/028; H01L 31/0296; H01L 31/0272; H01L 31/032; H01L 31/0368

(52) U.S. Cl. 136/255; 136/252; 136/256; 136/261; 136/258; 136/260; 136/264

(57) ABSTRACT

An exemplary system and method for forming a solar panel system includes manufacturing solar panel sheets via thin film solar technology that include a flashing overlap and a non-dry adhesive located on the bottom surface of the sheets such that the solar panel sheets form a moisture barrier on the roof while providing a renewable solar energy source. The solar panel system that forms a moisture barrier on the roof of a structure may include a non-glare surface treatment to provide the appearance of standard 30 year shingles. Additionally, the solar panel system may include a temperature/pressure/light transmissibility sensor system configured to notify a homeowner when the solar panel system is dirty, obscured, or should be changed to reverse current mode to melt snow or ice buildup.

### RELATED APPLICATIONS

This application claims the benefit under 35 U.S.C. §119(e) of U.S. Provisional Patent Application No. 61/295,842 filed Jan. 18, 2010 titled “System and Method for Forming Roofing Solar Panels,” which provisional application is incorporated herein by reference in its entirety.

### BACKGROUND

In recent years, societal consciousness of the problems relating to the environment and energy has been increasing throughout the world. Particularly, heating of the earth because of the so-called greenhouse effect due to an increase of atmospheric CO₂ has been predicted to cause serious problems. In view of this, there is an increased demand for means of power generation capable of providing clean energy without causing CO₂ build-up. In this regard, nuclear power generation has been considered advantageous in that it does not cause CO₂ build-up. However, there are problems with nuclear power generation such that it unavoidably produces radioactive wastes which are harmful for living things, and there is a probability that leakage of injurious radioactive materials from the nuclear power generation system will occur when the system is damaged. Consequently, there is an increased societal demand for early realization of a power generation system capable of providing clean energy without causing CO₂ build-up as in the case of thermal power generation and without causing radioactive wastes and radioactive materials as in the case of nuclear power generation.

There have been various proposals which are expected to meet such societal demand. Among those proposals, solar cells (i.e., photovoltaic elements) are expected to be a future power generation source since they supply electric power without causing the above mentioned problems and they are safe and can be readily handled. Particularly, public attention has been focused on a solar cell power generation system because it is a clean power generation system which generates electric power using sunlight. It is also evenly accessible at any place in the world and can attain relatively high power generation efficiency without requiring a relatively complicated large installation. Additionally, the use of solar cell power generation systems can also be expected to comply with an increase in the demand for electric power in the future without causing environmental destruction.

Incidentally, solar cells have been gaining in popularity since they are clean and non-exhaustible electric power sources. Additionally, a number of technological advances have been made that both improve the performance and ease of manufacturing the solar cells. These advances have resulted in the expansion of solar cells to an increasing number of homes and buildings.

In the case of installing a plurality of solar cell modules on a roof of a building, the process typically involves the placement of a predetermined number of the solar cell modules on independent structures on the roof. The solar cell module herein means a structural body formed by providing a plurality of solar cells, electrically connecting them to each other in series connection or parallel connection to obtain a solar cell array, and sealing said array into a panel-like shape. In the case of installing these solar cell modules on the roof, they are spacedly arranged on the roof at equal intervals, followed by electrically wiring them so that they are electrically connected with each other in series connection or parallel connection. The result of this process is generally called a solar cell module array. Traditional solar cell module arrays are placed on structural panels that are mechanically attached to a roof by fixing fasteners through the shingles, felt, and structural building material of a roof. The passing of mechanical fasteners through the elemental barrier layer of the roof generates a potential weak spot in the environmental barrier of the roof and may result in leaks or other environmental issues.

### SUMMARY

An exemplary system and method for forming a solar panel system includes manufacturing solar panel sheets via thin film solar technology that include a flashing overlap and a non-dry adhesive located on the bottom surface of the sheets such that the solar panel sheets form a moisture barrier on the roof while providing a renewable solar energy source.

In another exemplary embodiment, the solar panel system that forms a moisture barrier on the roof of a structure includes a non-glare surface treatment to provide the appearance of standard 30 year shingles. Additionally, in another exemplary embodiment, the solar panel system includes a temperature/pressure/light transmissibility sensor system configured to notify a homeowner when the solar panel system is dirty, obscured, or should be changed to reverse current mode to melt snow or ice buildup.

### BRIEF DESCRIPTION OF THE DRAWINGS

The accompanying drawings illustrate various embodiments of the present system and method and are a part of the specification. The illustrated embodiments are merely examples of the present system and method and do not limit the scope thereof.

FIG. 1 illustrates a solar panel system incorporated onto the roof of a house, according to one exemplary embodiment.

FIG. 2 illustrates a top view of a photovoltaic cell that can form the vapor barrier of a roofing system, according to one exemplary embodiment.

FIG. 3 illustrates a bottom view of a photovoltaic cell that can form the vapor barrier of a roofing system, according to one exemplary embodiment.

FIG. 4 illustrates a bottom cross-sectional view of a photovoltaic cell that can form the vapor barrier of a roofing system, according to one exemplary embodiment.

FIG. 5 illustrates a side cross-sectional view of a photovoltaic cell that can form the vapor barrier of a roofing system, according to one exemplary embodiment.

FIG. 6 is a side cross-sectional view illustrating the placement of the present solar panel system on the roof of a structure, according to one exemplary embodiment.

FIG. 7 is a side cross-sectional view illustrating the placement of the present solar panel system on the roof of a structure, according to another exemplary embodiment.

Throughout the drawings, identical reference numbers designate similar, but not necessarily identical, elements.

### DETAILED DESCRIPTION

An exemplary system and method for forming a solar panel system is disclosed herein. Specifically, An exemplary system and method for forming a solar panel system includes manufacturing solar panel sheets via thin film solar technology or other photovoltaic cell forming process that include a flashing overlap and a non-dry adhesive located on the bottom surface of the sheets such that the solar panel sheets form a moisture barrier on the roof while providing a renewable solar energy source. According to one exemplary embodiment, the solar panel system that forms a moisture barrier on the roof of a structure includes a non-glare surface treatment to provide the appearance of standard 30 year shingles. Additionally, in another exemplary embodiment, the solar panel system includes a temperature/pressure/light transmissibility sensor system configured to notify a homeowner when the solar panel system is dirty, obscured, or should be changed to reverse current mode to melt snow or ice buildup. Embodiments and examples of the present exemplary systems and methods will be described in detail below.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present disclosure.

Additionally, as used herein, and in the appended claims, the term “photovoltaic cell” shall be understood to mean any member or construct that is configured to produce a voltage when exposed to radiant energy.

As used herein, the terms “conductor”, “conducting”, or “conductive” are meant to be understood as any material which offers low resistance or opposition to the flow of electric current due to high mobility and high carrier concentration.

In the following description, for purposes of explanation, numerous specific details are set forth in order to provide a thorough understanding of the present system and method for forming a solar panel system. It will be apparent, however, to one skilled in the art, that the present method may be practiced without these specific details. Reference in the specification to “one embodiment” or “an embodiment” means that a particular feature, structure, or characteristic described in connection with the embodiment is included in at least one embodiment. The appearance of the phrase “in one embodiment” in various places in the specification are not necessarily all referring to the same embodiment.

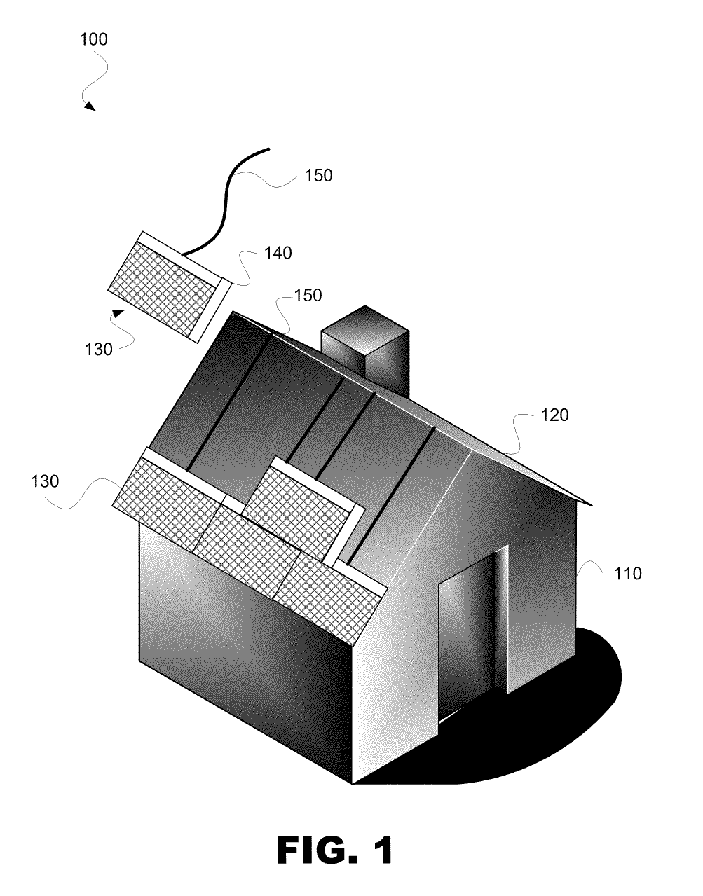

FIG. 1 illustrates a solar panel system incorporated onto the roof of a house, according to one exemplary embodiment. As illustrated in FIG. 1, the exemplary solar panel system (100) is configured to be fastened to the roof (120) of a house (110) or other structure. According to one exemplary embodiment, the solar panel system (100) includes a plurality of panels (130) formed with a flashing member (140) formed on the distal end thereof including a pigtail or other electric lead (150) protruding from the distal end of the panel (130). Additionally, according to one exemplary embodiment illustrated in FIG. 1, the exemplary panel (130) includes a flashing member (140) located on a side portion of the panel. This allows for a flashing member to be present on all abutting seams as the panels are fastened to a surface, as will be described in further detail below.

As shown in FIG. 1, a plurality of panels (130) are securely fastened to the roof (120) portion of the house (110) or other structure and not only provide the ability to generate electricity via exposure to the sun, but also provides the function and appearance of a moisture barrier such as a shingle. Further details of the exemplary structure and function of the exemplary panel (130) and its incorporation into the exemplary solar panel system (100) will be provided below.

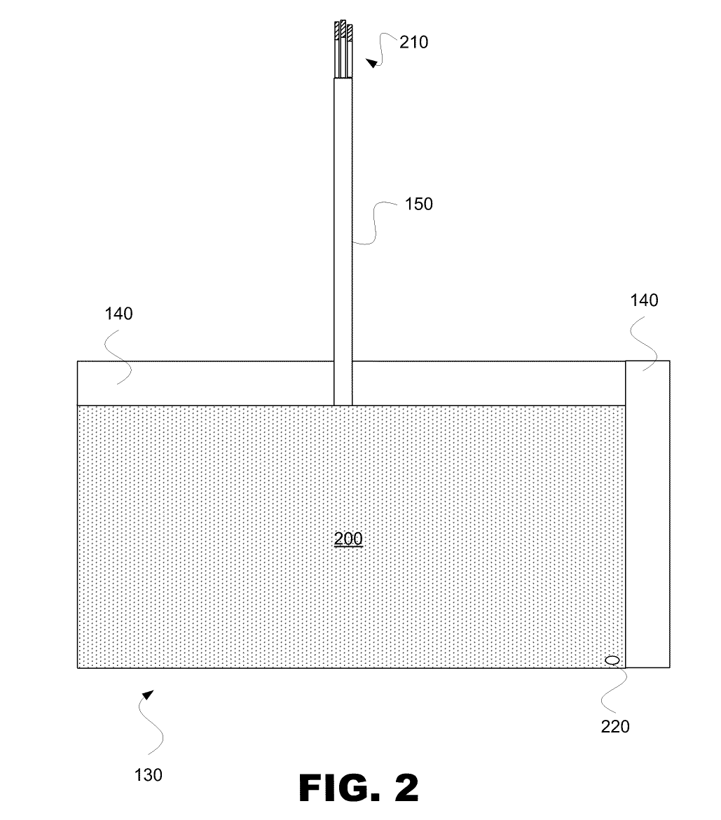

FIG. 2 illustrates a top view of a photovoltaic cell that can form the vapor barrier of a roofing system, according to one exemplary embodiment. While the exemplary photovoltaic cell (200) of FIG. 2 is illustrated as rectangular in shape, it will be understood that the exemplary photovoltaic cell (200) may assume any number of shapes and or shape combinations in order to adequately cover the roof of a house or other building. According to one exemplary embodiment, the exemplary photovoltaic cell is manufactured to custom fit the dimensions of a roof by the manufacturer and shipped to the home site for installation. According to this exemplary embodiment, the roofing contractor measures the dimensions of the roof to be worked upon and provides the dimensions to the manufacturing facility for custom manufacture. Additionally, according to one exemplary embodiment, the exemplary photovoltaic cell (200) may be dimensioned to be integrated with traditional shingles, if desired.

Continuing with FIG. 2, the exemplary panel (130) includes a photovoltaic cell (200) configured to produce a voltage when exposed to radiant energy, such as sunlight. According to one exemplary embodiment, the photovoltaic cell may be any one of a single crystal silicon cell, a polycrystal silicon cell, a ribbon silicon cell, and/or an amorphous silicon cell. As illustrated, a flashing (140) configured to provide a vapor proof barrier when inter-lockingly placed on the roof of a home or building is formed on the distal, or up-pitch side of the exemplary panel (130). Additionally, an exemplary flashing (140) is formed on the right side, as viewed from the top in FIG. 2, of the exemplary panel (130). While the side flashing member (140) is described as being on the right side, the side flashing member may be on either or both sides, depending on the intended application of the system. According to one exemplary embodiment, the flashing is formed using traditional shingle flashing material, including, but in no way limited to, sheet metals such as aluminum, copper, lead-coated copper, lead, stainless steel, galvanized steel, zinc, and Galvalume or membrane flashings including but in no way limited to any one of a polymer based film, polyester film, fibrous glass mesh sheets, and/or a resinous adhesive.

At the distal end of the panel (130), a pigtail or electrical lead (150) exits the photovoltaic cell (200). According to one exemplary embodiment, the pigtail or electrical lead (150) includes a number of conductors (210) enclosed therein. The pigtail or electrical lead (150) is configured to form a conduit for any electricity generated by the photovoltaic cell (200) and channel the generated electricity to a bank of batteries, the grid, or another power storage/distribution member (not shown). According to one exemplary embodiment, the pigtail or electrical lead (150) is disposed on top of the flashing (140) such that the flashing may form a complete seal on the roof of the structure it is fastened to in order to form a vapor barrier thereon.

Additionally, as illustrated in FIG. 2, the exemplary panel (130) may also include a sensor (220) for sensing light, temperature and/or pressure. For example, according to one exemplary embodiment, the sensor (220) may be a piezoelectric crystal based sensor configured to detect weight on the panel (130). According to one embodiment, when the sensor detects weight on the panel (130), it may notify a monitoring system and alert the homeowner to check for snow, leaves, or other debris. In another exemplary embodiment, the sensor may be a temperature sensor configured to notify the home owner when snow and/or ice are likely to cover the panel and prevent or deteriorate the panel's ability to produce electricity. In this embodiment, when the sensor detects a low temperature, the panel (130) may be configured to reverse the current and create a thermal effect within the photovoltaic cell (200) to melt any ice and/or snow that may be on the panel (130). According to yet another exemplary embodiment, the panel (130) may include a light sensor configured to notify the user when the generation of electricity is not possible so that the user can investigate any reason for such a condition.

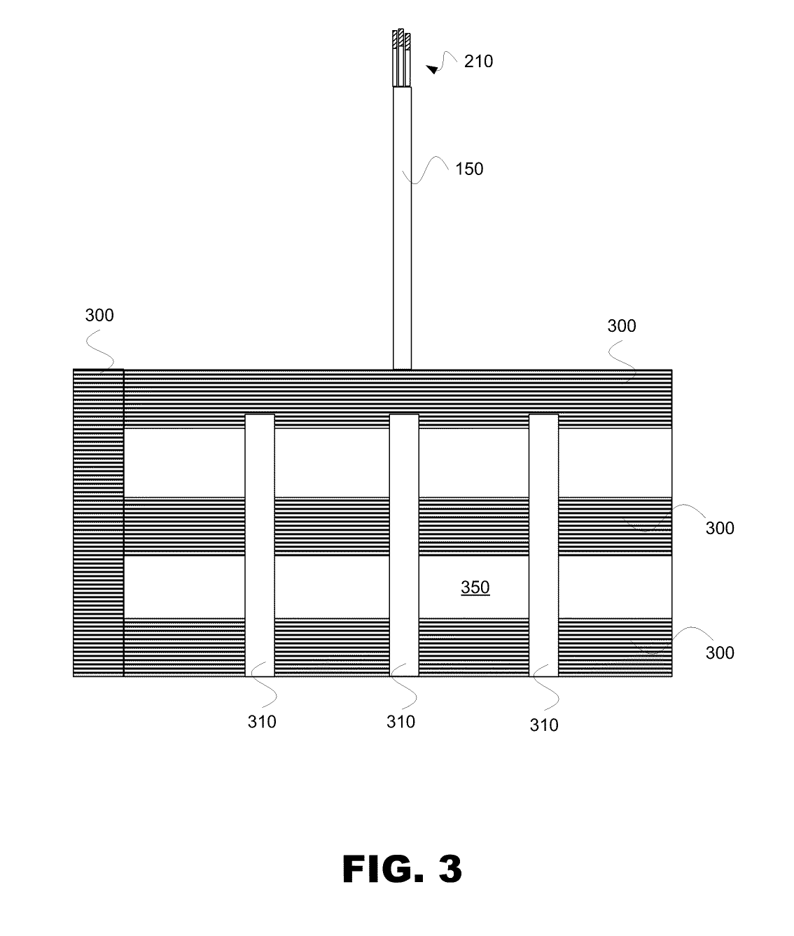

FIG. 3 illustrates a bottom view of a photovoltaic cell that can form the vapor barrier of a roofing system, according to one exemplary embodiment. As illustrated in FIG. 3, the bottom surface of the exemplary panel (130) includes a back surface (350) having a number of adhesive strips (300) horizontally positioned on the back surface of the panel. A vertical adhesive strip (300) is also located on the side flashing member (140). According to one exemplary embodiment, the adhesive strips (300) are formed of a non-hardening adhesive material, such as tar or other adhesive materials, and is configured to have a barrier layer removed and the adhesive to be affixed to the roof of a house or other building. According to one exemplary embodiment illustrated in FIG. 3, a plurality of adhesive strips (300) may be formed on the back surface (350) of the panel (130) in order to prevent bending of the panel in the event of high winds or other extreme weather conditions. The plurality off adhesive strips (300) also prevents the insertion of debris and/or pests under the panel (130). According to the exemplary embodiment shown in FIG. 3, three horizontal swaths of the adhesive strips (300) are present on the back surface (350) of the panel (130). However, any number of adhesive strips (300) may be formed on the back surface (350) of the panel (130).

Additionally, as illustrated in FIG. 3, a number of gaps or lead channels (310) are alternatively formed in the adhesive strips (300). According to one exemplary embodiment, the lead channels (310) are configured to receive the pigtail or electrical lead (150) of other panels (130) and provide a channel or conduit for the electrical leads (150) of other panels to traverse on their route to the top of the roof. According to this exemplary embodiment, the lead channel (310) is formed as vertical sections of the back surface (350) without any adhesive (300) or other structural material, allowing for the free flow and expansion/contraction of the electrical leads (150) of other panels (130). According to the exemplary embodiment illustrated in FIG. 3, three lead channels (310) are provided in order to allow a quarterly offset of the panels (130) being placed on a roof. However, any number of lead channels (310) may be formed.

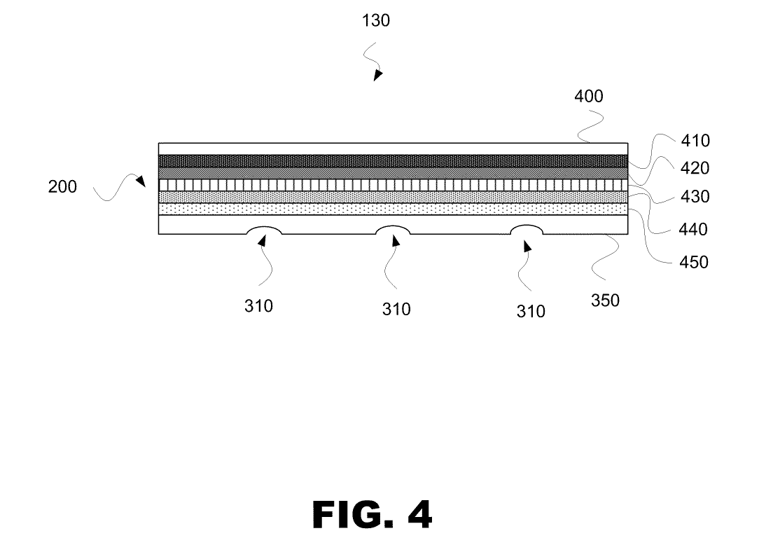

FIG. 4 illustrates a bottom cross-sectional view of a photovoltaic cell that can form the vapor barrier of a roofing system, according to one exemplary embodiment. As illustrated in FIG. 4, the panel (130) includes a photovoltaic cell (200) that is built upon a back surface (350). As illustrated, the back surface is formed such that a plurality of lead channels (310) are formed to allow for the vertical running of electrical leads (150) from the bottom panels (130) to the top ridge of the house for collection.

On top of the back surface (350) is the plurality of layers that form the photovoltaic cell (200). According to one exemplary embodiment illustrated in FIG. 4, the photovoltaic cell (200) includes, but is in no way limited to a semiconductor having a back contact (450), a p-type semiconductor (440), an n-type semiconductor (430), a contact grid (420), an anti-reflective coating (410), and a cover glass substrate (400). According to one exemplary embodiment, the p-type semiconductor (440) and the n-type semiconductor (430) are separated by a P—N junction absorber layer (not shown).

According to the exemplary embodiment illustrated in FIG. 4, When the holes and electrons mix at the junction between N-type and P-type silicon, neutrality is disrupted and free electrons on the N-type semiconductor (430) cross to the p-type semiconductor (440) until an electric field separating the two sides. This electric field acts as a diode, allowing (and even pushing) electrons to flow from the P-type semiconductor (440) to the N-type semiconductor (430) creating an electric field acting as a diode in which electrons can only move in one direction.

When light, in the form of photons, hits the photovoltaic cell (200), its energy frees electron-hole pairs. Each photon with enough energy will normally free exactly one electron, and result in a free hole as well. If this happens close enough to the electric field, or if free electron and free hole happen to wander into its range of influence, the field will send the electron to the N-type semiconductor (430) and the hole to the P-type semiconductor (440). This causes further disruption of electrical neutrality, and if we provide an external current path, electrons will flow through the path to their original side, the P-type semiconductor (440), to unite with holes that the electric field sent there, doing work along the way. The electron flow provides the current, and the cell's electric field causes a voltage. With both current and voltage, power is produced.

The back contact (450) and the contact grid (420) are formed to capture the power and transmit it, via the electrical leads (150) to a power storage location (not shown). Additionally, as silicon is a very shiny material, it is very reflective. Since photons that are reflected can't be used by the cell, the antireflective coating (410) is applied to the top of the photovoltaic cell (200) to reduce reflection losses. Additionally, the cover glass (400) is placed on the top if the photovoltaic cell (200) in order to protect the cell from the elements. According to one exemplary embodiment, the cover glass (400) is processed such that its top view of the panel (130) is substantially similar to a traditional 30 year asphalt shingle. The asphalt shingle appearance may be provided to the cover glass (400) via any number of surface treatment methods including, but in no way limited to, etching, painting, and the like. Once constructed, a plurality of panels (130) including photovoltaic cells (200) are placed in series and parallel to achieve useful levels of voltage and current that is transmitted through the electrical lead (150).

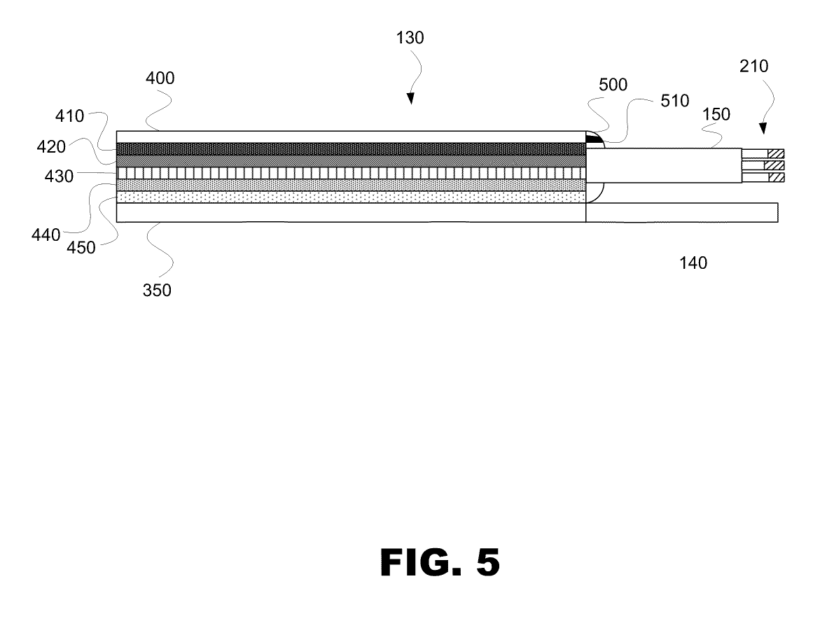

FIG. 5 illustrates another side cross-sectional view of a photovoltaic cell that can form the vapor barrier of a roofing system, according to one exemplary embodiment. As illustrated in FIG. 5, the vertically placed lead channels (310) are not seen traversing the back surface (350). However, as shown, a flashing member (140) is coupled to the back surface (350) in order to allow the exemplary panel system (130) to serve as a shingle/water barrier for a roof. According to one exemplary embodiment, the flashing member (140) may be formed of the same material as the back surface (350) and merely extend beyond the termination of the panel (130). Alternatively, the flashing (140) may be coupled to the back surface by an adhesive, mechanical coupling, or any other fastening means.

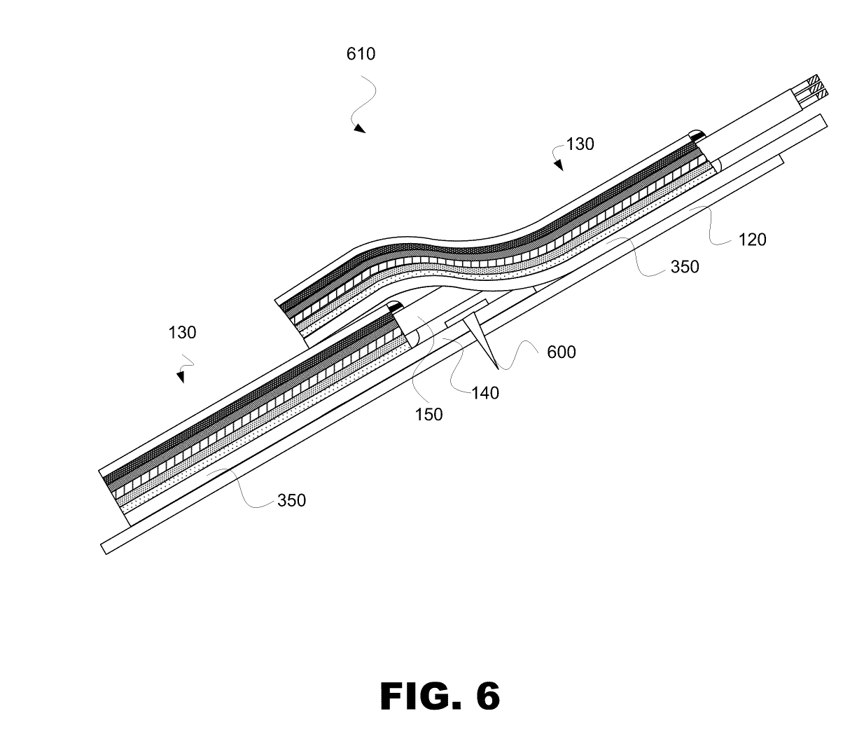

FIG. 5 also illustrates the coupling of the electrical lead (150) including conductors (210) to the photovoltaic cell (200), according to one exemplary embodiment. As shown, the conductors (210) may be coupled to one or more of the back contact (450) and the contact grid (420) and then pass through the electrical lead (150). As shown, a lead housing (500) couples the electrical lead (150) to the photovoltaic cell (200). According to one exemplary embodiment, the lead housing (500) is configured to weather proof the photovoltaic cell (200) and conductors (210) while securing the interface between the photovoltaic cell and the electrical lead (150). According to one exemplary embodiment, the lead housing (510) is made of an epoxy resin, a polymer material, or some other waterproof material configured to encapsulate the photovoltaic cell (200). Additionally, as illustrated in FIG. 5, the lead housing (500) includes a vent member (510) configured to allow for the release of heat and gas created by the photovoltaic cell (200). As is illustrated in FIG. 6, the exhaust released through the vent (510) will be allowed to escape the resulting matrix of panels via the lead channel (310). Alternatively, the photovoltaic cell may be vented through the casing of the electrical lead (150).

FIG. 6 illustrates a side cross-sectional view illustrating the placement of the present solar panel system on the roof of a structure, according to one exemplary embodiment. As illustrated in FIG. 6, the exemplary panels (130) are fastened to the roof (120) of a house or other structure via a fastener (600) such as a nail passing through the flashing (140) portion of the structure. As illustrated, the assembled matrix (610) includes an overlap of the panels on the proximal side of the upper most panel to create a shingle effect. According to one exemplary embodiment, this shingled effect will create a weather tight barrier between the panel matrix (610) and the roof of the structure (120). Additionally, as illustrated in FIG. 6, the electrical lead (150) is able to pas through the lead channels (310) of the upper-most panels (130).

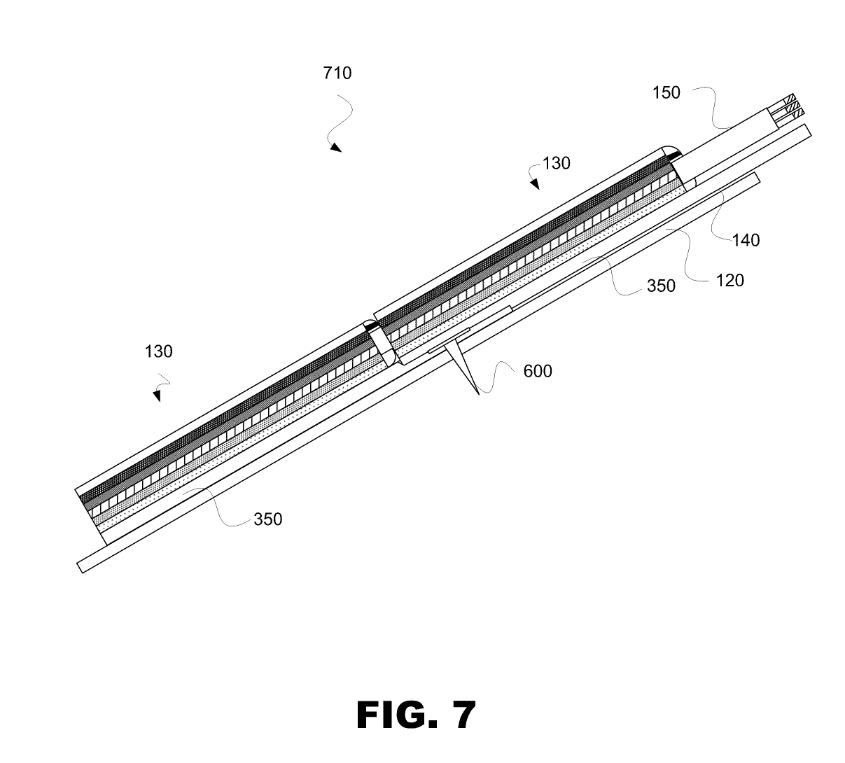

FIG. 7 illustrates an alternative exemplary configuration for placing the present solar panel system on the roof of a structure. According to the exemplary embodiment illustrated in FIG. 7, the assembled matrix (710) includes the exemplary panels (130) butted against each other with the flashing (140) overlapping to create a water barrier. According to this exemplary embodiment, the flashings (140) form a weather proof membrane on the surface of the roof (120) without overlapping the actual panels (130) themselves. Rather, the flashings (140) overlap and form the barrier.

While the present exemplary system has been described in the context of a generic silicon PV cell, any number of photo voltaic cell structures may be incorporated by the present exemplary system and method including, but in no way limited to, monocrystalline silicon cells, multicrystalline silicon cells, micromorphous silicon cells, thick film silicon cells, amorphous silicon cells, cadmium telluride (CdTe) based cells, copper indium diselenide (CIS) based cells, inverted metamorphic multi-junction solar cells, and the like.

As noted above, the present exemplary system may be manufactured to custom fit the roof of a building or other structure. Alternatively, a number of non-functioning panels may be formed and incorporated on the roof of a house or building to allow for use of the present system without design manufacturing. Specifically, according to one exemplary embodiment, each of the above-mentioned exemplary panels (130) may be manufactured according to a standard range of sizes, each panel having the flashings (140) configured to overlap and form the weather proof membrane or barrier. However, during installation, when the contractor is presented with less than a standard area to cover and there is not a standard size panel available for use, or if a valley or exhaust pipe is encountered, a solar blank may be used. According to this exemplary embodiment, the solar blank panels are non-functioning panels having a back surface entirely covered with weather proof adhesive and including the previously explained flashings (140). According to this exemplary embodiment, when a non-uniform area is presented, the non-functioning panel may be cut to fit the non-uniform area, while maintaining the weather-proof barrier. Consequently, irregular shaped surfaces may benefit from the present exemplary system and method without the need for custom manufacturing.

In conclusion, the present exemplary system and method for forming a solar panel system includes manufacturing solar panel sheets via thin film solar technology or other photovoltaic cell forming process that include a flashing overlap and a non-dry adhesive located on the bottom surface of the sheets such that the solar panel sheets form a moisture barrier on the roof while providing a renewable solar energy source. According to one exemplary embodiment, the solar panel system that forms a moisture barrier on the roof of a structure includes a non-glare surface treatment to provide the appearance of standard 30 year shingles. Additionally, in another exemplary embodiment, the solar panel system includes a temperature/pressure/light transmissibility sensor system configured to notify a homeowner when the solar panel system is dirty, obscured, or should be changed to reverse current mode to melt snow or ice buildup.

The preceding description has been presented only to illustrate and describe exemplary embodiments of the present system and method. It is not intended to be exhaustive or to limit the system and method to any precise form disclosed. Many modifications and variations are possible in light of the above teaching. It is intended that the scope of the system and method be defined by the following claims.

What is claimed is:

1. An apparatus comprising:
a photovoltaic cell including a back surface;
wherein said back surface is coupled to a weather proof flashing configured to be secured to a roof of a structure.

2. The apparatus of claim 1, wherein said photovoltaic cell further comprises a sensor.

3. The apparatus of claim 2, wherein said sensor comprises one of a thermal sensor, a pressure sensor, or a light transmissibility sensor.

4. The apparatus of claim 1, wherein said back surface further comprises a non-drying adhesive.

5. The apparatus of claim 4, wherein said back surface further comprises a plurality of lead channels defined in said back surface, said lead channels being configured to provide for the passage of electrical leads while maintaining a substantially planar orientation of said back surface.

6. The apparatus of claim 1, further comprising an electrical lead coupled to said photovoltaic cell.

7. The apparatus of claim 6, wherein said electrical lead comprises a pigtail.

8. The apparatus of claim 6, further comprising a lead housing hermetically sealing said electrical lead to said panel.

9. The apparatus of claim 8, wherein said lead housing further comprises a vent.

10. The apparatus of claim 1, wherein said photovoltaic cell further comprises a semiconductor having a back contact, a p-type semiconductor, an n-type semiconductor, a contact grid, an anti-reflective coating, and a cover glass substrate.

11. The apparatus of claim 10, wherein said cover glass substrate is surface treated to appear as asphalt shingles.

12. The apparatus of claim 11, wherein said cover glass substrate is treated by one of a painting process or an etching process.

13. The apparatus of claim 1, wherein said photovoltaic cell comprises one of a monocrystalline silicon cell, a multicrystalline silicon cell, a micromorphous silicon cell, a thick film silicon cell, an amorphous silicon cell, a cadmium telluride (CdTe) based cell, a copper indium diselenide (CIS) based cell, or an inverted metamorphic multijunction solar cell.

14. The apparatus of claim 1, wherein said flashing extends beyond two edges of said photovoltaic cell.
